(19) United States
(12) Patent Application Publication
(10) Pub. No.: US 2019/0341352 A1
(43) Pub. Date: Nov. 7, 2019

(54) TAPERED CORNER PACKAGE FOR EMI SHIELD

(71) Applicant: QUALCOMM Incorporated, San Diego, CA (US)

(72) Inventors: Hong Bok WE, San Diego, CA (US); Chin-Kwan KIM, San Diego, CA (US); Jaehyun YEON, San Diego, CA (US); Manuel ALDRETE, Encinitas, CA (US); David Fraser RAE, San Diego, CA (US)

(21) Appl. No.: 15/968,774

(22) Filed: May 2, 2018

(51) Int. Cl. H01L 23/552; H01L 23/31; H01L 23/498; H01L 21/48; H01L 21/56; H01L 21/78; H01L 21/683; H01L 21/3105; H01L 23/29

(52) U.S. Cl. CPC H01L 23/552; H01L 23/3114; H01L 23/498; H01L 21/4853; H01L 21/565; H01L 21/561; H01L 24/16; H01L 21/78; H01L 21/6836; H01L 21/485; H01L 21/31058; H01L 23/293; H01L 2221/68327; H01L 21/568

(57) ABSTRACT

A semiconductor package comprises a substrate, a die mounted on the substrate, and a mold formed over the die and on the substrate, the mold having a top surface and a plurality of tapered side surfaces, wherein the tapered side surfaces provide uniform thickness of an electromagnetic interference (EMI) shielding film.

### BACKGROUND

### Field

Aspects of the present disclosure relate generally to a semiconductor package having an electromagnetic interference (EMI) shield and, more particularly, to a semiconductor package having a tapered EMI shield.

### Background

Semiconductor devices are commonly used in electronic products such as cellular phones, video cameras, portable music players, printers, computers, etc. A trend for semiconductor devices is miniaturization, lightness and multifunction. Semiconductor devices emit electromagnetic radiation in the range from approximately 50 MHz to 3 GHz depending on the speed of the microprocessor. As the speed of microprocessor continues to increase, and as semiconductor devices continue to get smaller, there is a gradual increase in electromagnetic radiation emission. Electromagnetic radiation acts as electromagnetic interference (EMI) or radio frequency interference (RFI) that hinders the operation of other electronic equipment that may result in equipment failures. That is, EMI or RFI acts as a disturbance that may affect an electrical circuit by electromagnetic induction, electrostatic coupling, or conduction. The disturbance may degrade the performance of the circuit or even stop it from functioning. Current semiconductor devices include EMI shields that are formed by spraying, sputtering, or plating that have resulted in non-uniform top and side surface thicknesses. Accordingly, there is a need for a semiconductor device and process for forming an EMI shield on the semiconductor device having similar top and side surface thicknesses using existing process technology.

### SUMMARY

The following presents a simplified summary of one or more aspects or embodiments to provide a basic understanding of such aspects. This summary is not an extensive overview of all contemplated aspects, and is intended to neither identify key or critical elements of all aspects nor delineate the scope of any or all aspects. Its sole purpose is to present some concepts of one or more aspects in a simplified form as a prelude to the more detailed description that is presented later.

A method of manufacturing a semiconductor package according to one aspect is described. The method comprises mounting and bonding a die on a surface of a substrate, forming a mold over the die and on the substrate, cutting the mold having a top surface and a plurality of side surfaces, wherein the side surfaces are tapered cut to allow uniform thickness during spraying or sputtering of an EMI shielding film, and spraying or sputtering the mold with the EMI shielding film. The bonding of the die may be done by surface mounted components (SMC) using a thermally and/or electrically conductive adhesive. The conductive adhesive may include solder and/or epoxy. The taper cutting may be done with a diamond saw.

A semiconductor package according to one aspect is described. The semiconductor package comprises a substrate, a die mounted on the substrate, and a mold formed over the die and on the substrate, the mold having a top surface and a plurality of tapered side surfaces, wherein the tapered side surfaces provide uniform thickness of an electromagnetic interference (EMI) shielding film. The tapered side surfaces provide uniform thickness of the EMI shielding film during spraying or sputtering of the EMI shielding film. The mold may comprise synthetic resin. The EMI shielding film may comprise at least one or more layers of a metallic element comprising at least one of Ni, Cu, Ag, or Fe. The EMI film thickness is approximately 4000 Å to 8000 A. The tapered side surfaces have an incident angle of approximately 20% to 65% to maintain uniform thickness. In another aspect, each of the tapered side surfaces may be tapered cut to a plurality of cut surfaces having different incident angles.

These and other aspects of the invention will become more fully understood upon a review of the detailed description, which follows. Other aspects of the invention will become apparent to those of ordinary skill in the art, upon reviewing the following description of specific, exemplary aspects of the invention in conjunction with the accompanying figures.

### BRIEF DESCRIPTION OF THE DRAWINGS

FIG. 1 is a side cross-sectional view illustrating a module package having an EMI shield of the prior art;

FIG. 2 is a side cross-sectional view illustrating a semiconductor system-in-package (SIP) module package having an EMI shield according to one aspect of the invention; and

FIGS. 3A-3D illustrate a method of manufacturing the semiconductor SIP module in accordance to one aspect of the invention.

### DETAILED DESCRIPTION

The detailed description set forth below, in connection with the appended drawings, is intended as a description of exemplary aspects and is not intended to represent the only aspects in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

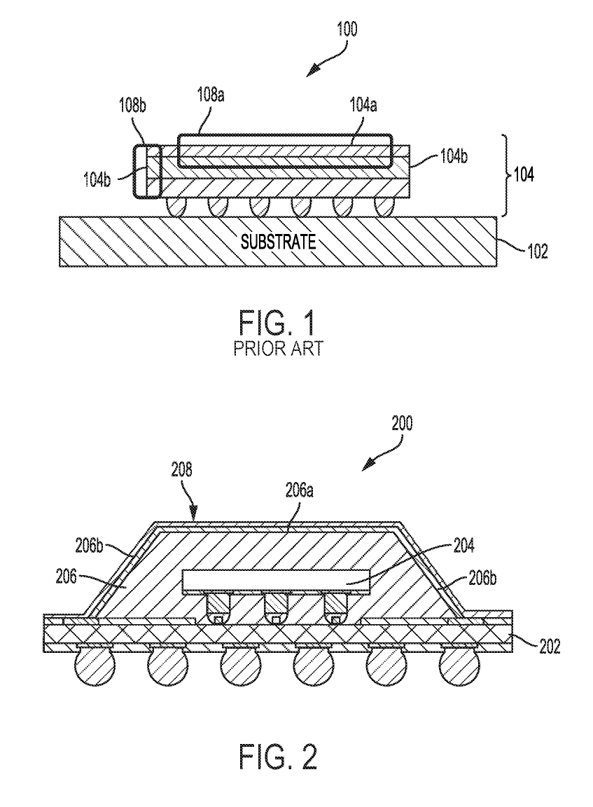

FIG. 1 is a side cross-sectional view illustrating a module package 100 having an EMI shield of the prior art. The module package 100 includes a substrate 102 and a chip 104. The chip 104 has a top surface 104a and side surfaces 104b. The top surface 104a and side surfaces 104b are sprayed, sputtered, or plated with EMI shielding films 108a and 108b, respectively, for shielding electromagnetic interference. A problem with the current process is the EMI shielding film 108a for the top surface 104a is almost 3× thicker than EMI shielding film 108b for the side surfaces 104b. That is, spraying is typically done in one step and in order to get the minimum thickness of approximately 2.8 nm for EMI shielding film 108b (for the side surfaces 104b), this typically results in EMI shielding film 108a (for the top surface 104a) being unnecessary thick at approximately 9 nm. In addition, it costs more and it takes longer to spray 9 nm for EMI shielding film 108a (for the top surface 104a). As such, there is a need for a better process of providing similar thickness for the top surface 104a and side surfaces 104b.

FIG. 2 is a side cross-sectional view illustrating a semiconductor system-in-package (SIP) module package 200 having an EMI shield according to one aspect of the invention. The SIP module package 200 may include a printed circuit board (PCB) 202, a chip 204, and a mold 206. The mold 206 has a top surface 206a and side surfaces 206b that are tapered as further explained in the process of manufacturing the SIP module package 200 below. In other words, the mold 206 is tapered or sloped shaped on the side to reduce non-uniformity during spraying or sputtering of EMI shielding film. That is, by providing the tapered or sloped side surfaces 206b, the SIP module package 200 can have similar thicknesses at the top surface 206a and the side surfaces 206b (after spraying or sputtering of EMI shielding film). The mold 206 may be a synthetic resin. The top surface 206a and the side surfaces 206b may be coated with an EMI shielding film 208 for shielding electromagnetic interference. The EMI shielding film 208 may comprise one or more layers of a metallic element comprising at least one of Ni, Cu, Ag, or Fe. The EMI shielding film 208 may be sprayed, sputtered, or plated on the surface of the mold 206. The thickness of the EMI shielding film 208 may be, for example, approximately 4000 Å to 8000 Å. The SIP module package 200 may be formed using current compression molding using existing process steps. The SIP module package 200 improves on current process because it does not need to spur the top surface more than necessary (e.g., ˜3x the thickness of side surfaces) in order to have minimum side surface thickness. In addition, the SIP module package 200 is less expensive to process because it does not take as long to sputter the top surface 206a. The incident or sloped angle of the side surface 206b may be approximately 20% to 65% to maintain uniform thickness of the shielding film 208 during spraying or sputtering. In another aspect, each of the tapered or sloped side surfaces 206b may be further tapered cut to a plurality of surfaces having different incident or sloped angles.

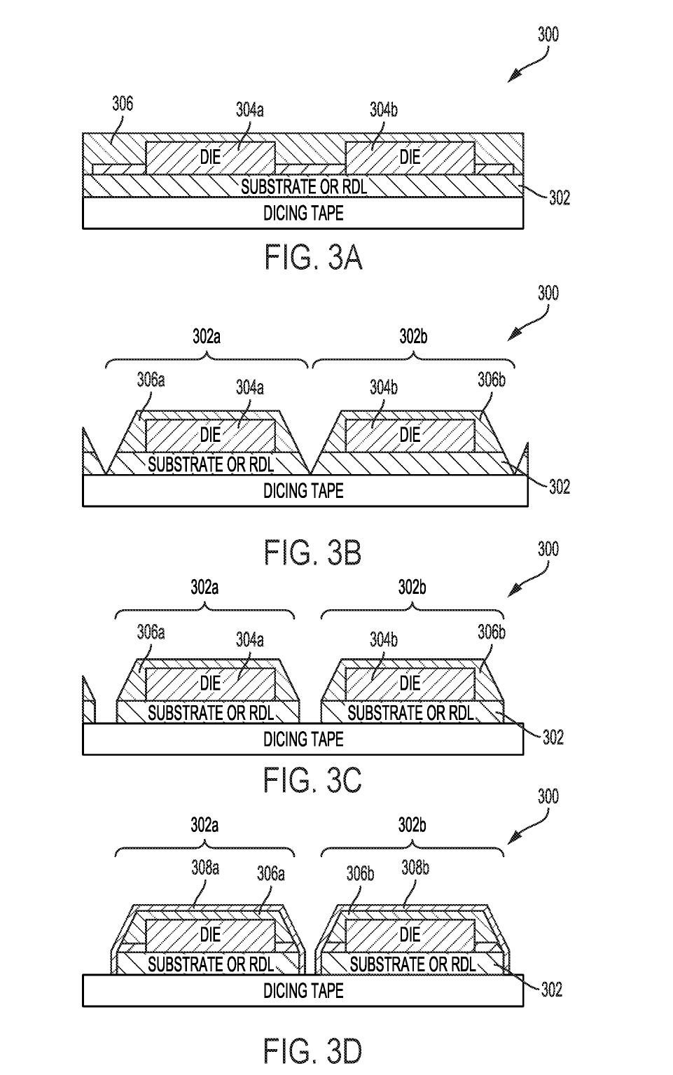

FIGS. 3A-3D illustrate a method of manufacturing the semiconductor SIP module in accordance to one aspect of the invention. While the disclosed method is illustrated and described as a series steps, the ordering of such steps are not to be limited to such order. For example, some steps may occur in different orders and/or concurrently with other steps apart from those illustrated and described herein. FIG. 3A illustrates attaching or mounting individual chips or die 304a and 304b on the surface of a substrate 302 of wafer or strip 300. The individual chips or die 304a and 304b are then bonded on the surface of the substrate 302 of wafer or strip 300. These steps are known as surface mounted components (SMC) and die bonding. That is, the chips or die 304a and 304b are attached or mounted on the surface of substrate 302 and then bonded together using a thermally and/or electrically conductive adhesive such as solder or epoxy containing metal or other conductive particles. Mold 306 is then formed over the chips or die 304a and 304b and on the surface of substrate 302. The mold 306 may be a synthetic resin.

Next, FIG. 3B illustrates the mold 306 being tapered cut to separate chips or die 304a and 304b in the wafer or strip 300. As a result, two separate molds 306a and 306b are formed allowing the top surface and side surfaces of each of the molds 306a and 306b to be exposed. This step is known as the first singulation step of taper cutting the molds 306a and 306b into respective semiconductor module packages 302a and 302b. That is, the first singulation step is performed to externally expose the top and side surfaces of each semiconductor SIP module package 302a and 302b to allow uniform thickness during spraying or sputtering of EMI shielding film on the top surface and side surfaces of the molds 306a and 306b. The molds 306a and 306b may be tapered cut, for example, with a diamond saw. The incident or sloped angle of the side surfaces of the molds 306a and 306b may be approximately 20% to 65% to maintain uniform thickness of the EMI shielding film.

FIG. 3C illustrates the molds 306a and 306b being completely cut from one another. In particular, the substrate 302 is completely cut separating the molds 306a and 306b from one another forming separate SIP module packages 302a and 302b, respectively.

FIG. 3D illustrates the SIP module package 302a and 302b, which have been completely cut, being placed in a sputtering chamber for EMI shielding. The EMI shielding may be by sputtering, spraying, or plating of EMI shielding film 308a and 308b on the molds 306a and 306b, respectively. The wall thickness of EMI shielding film 308a and 308b is approximately the same because the side surfaces of the molds 306a and 306b are tapered cut. A benefit of this process is cost reduction because it is not necessary to sputter a thicker top surface in order to achieve a minimum side surface thickness, e.g., of approximately 2.8 nm. In addition, the processing time is reduced because it does not require the additional time to sputter the approximately 3× thicker top surface as compared to the side surface as in the prior art. In another aspect, each of the side surfaces of the molds 306a and 306b may be further tapered cut to a plurality of surfaces having different incident or sloped angles.

When sputtering, a plasma gas is filled in the sputtering chamber at a certain pressure, and then power is supplied to the sputtering chamber to allow a target metal to be deposited on the exposed tapered side and top surfaces of the molds 306a and 306b. The sputtering step as illustrated in FIG. 3D may be performed by using a magnetron sputtering system, or the co-sputtering device. The sputtering step may be performed for approximately 20-30 mins. The thickness of the EMI shielding film 308a and 308b may be approximately 4000 Å to 8000 Å. The EMI shielding film 308a and 308b may be coated on the surface of the molds 306a and 306b, respectively, with one or more layers of a metallic element comprising at least one of Ni, Cu, Ag, or Fe, which thereby shields EMI emitted from the SIP module packages 302a and 302b, respectively.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling between two objects. For example, if object A physically touches object B, and object B touches object C, then objects A and C may still be considered coupled to one another—even if they do not directly physically touch each other. For instance, a first die may be coupled to a second die in a package even though the first die is never directly physically in contact with the second die.

One or more of the components, steps, features and/or functions illustrated in the figures may be rearranged and/or combined into a single component, step, feature or function or embodied in several components, steps, or functions. Additional elements, components, steps, and/or functions may also be added without departing from novel features disclosed herein. The apparatus, devices, and/or components illustrated in the figures may be configured to perform one or more of the methods, features, or steps described herein. The novel algorithms described herein may also be efficiently implemented in software and/or embedded in hardware.

It is to be understood that the specific order or hierarchy of steps in the methods disclosed is an illustration of exemplary processes. Based upon design preferences, it is understood that the specific order or hierarchy of steps in the methods may be rearranged. The accompanying method claims present elements of the various steps in a sample order, and are not meant to be limited to the specific order or hierarchy presented unless specifically recited therein.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language of the claims, wherein reference to an element in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover: a; b; c; a and b; a and c; b and c; and a, b and c. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112, sixth paragraph, unless the element is expressly recited using the phrase “means for” or, in the case of a method claim, the element is recited using the phrase “step for.”

What is claimed is:

1. A semiconductor package, comprising:
a substrate:
a die mounted on the substrate; and
a mold formed over the die and on the substrate, the mold having a top surface and a plurality of tapered side surfaces, wherein the tapered side surfaces provide uniform thickness of an electromagnetic interference (EMI) shielding film.

2. The semiconductor package of claim 1, wherein the semiconductor package is a system-in-package (SIP) module package.

3. The semiconductor package of claim 1, wherein the mold top surface and plurality of tapered side surfaces have similar EMI film thickness.

4. The semiconductor package of claim 1, wherein the tapered side surfaces provide uniform thickness of the EMI shielding film during spraying or sputtering of the EMI shielding film.

5. The semiconductor package of claim 1, wherein the mold comprises synthetic resin.

6. The semiconductor package of claim 1, wherein the EMI shielding film comprises at least one or more layers of a metallic element comprising at least one of Ni, Cu, Ag, or Fe.

7. The semiconductor package of claim 1, wherein the EMI film thickness is approximately 4000 Å to 8000 Å.

8. The semiconductor package of claim 1, wherein the tapered side surfaces have an incident angle of approximately 20% to 65%.

9. The semiconductor package of claim 1, wherein each of the tapered side surfaces has a plurality of cut surfaces having different incident angles.

10. A method of manufacturing a semiconductor package, comprising:
mounting and bonding a die on a surface of a substrate;
forming a mold over the die and on the substrate;
cutting the mold having a top surface and a plurality of side surfaces, wherein the side surfaces are tapered cut to allow uniform thickness during spraying or sputtering of an EMI shielding film; and
spraying or sputtering the mold with the EMI shielding film.

11. The method of claim 10, wherein the bonding is done by surface mounted components (SMC) using a thermally and/or electrically conductive adhesive.

12. The method of claim 11, Therein the conductive adhesive includes solder and/or epoxy.

13. The method of claim 10, wherein the mold comprises synthetic resin.

14. The method of claim 10, wherein the taper cutting is done with a diamond saw.

15. The method of claim 10, wherein the tapered side surfaces have an incident angle of approximately 20% to 65%.

16. The method of claim 10, wherein each of the side surfaces is tapered cut to a plurality of cut surfaces having different incident angles.

17. The method of claim 10, wherein the semiconductor package is a system-in-package (SIP) module package.

18. The method of claim 10, wherein the mold top surface and plurality of tapered side surfaces have similar EMI film thickness.

19. The method of claim 16, wherein the EMI film thickness is approximately 4000 Å to 8000 Å.

20. The method of claim 10, wherein the EMI shielding film comprises at least one or more layers of a metallic element comprising at least one of Ni, Cu, Ag, or Fe.
